(19) United States
(12) Patent Application Publication
(10) Pub. No.: US 2022/0216374 A1
(43) Pub. Date: Jul. 7, 2022

(54) Lighting-emitting Diode Chip and Manufacturing Method, Display Device

(71) Applicant: CHONGQING KONKA PHOTOELECTRIC TECHNOLOGY RESEARCH INSTITUTE CO., LTD., Chongqing (CN)

(72) Inventors: Tao Wang, Yangzhou (CN); CHIA-HUI SHEN, Tainan (TW); KAI-YI WU, Xinzhu (TW)

(73) Assignee: CHONGQING KONKA PHOTOELECTRIC TECHNOLOGY RESEARCH INSTITUTE CO., LTD., Chongqing (CN)

(21) Appl. No.: 17/704,003

(22) Filed: Mar. 25, 2022

Related U.S. Application Data
(63) Continuation of application No. PCT/CN2021/083586, filed on Mar. 29, 2021.

(30) Foreign Application Priority Data
Nov. 25, 2020 (CN) 2020113375646

(51) Int. Cl. H01L 33/38; H01L 25/075; H01L 33/00; H01L 33/20

(52) U.S. Cl. CPC H01L 33/382; H01L 25/0753; H01L 2933/0016; H01L 33/20; H01L 33/005

(57) ABSTRACT

The disclosure relates to a light-emitting diode chip and a manufacturing method thereof, and a display device. The light emitting diode chip includes a transparent substrate, an epitaxial layer, a first electrode and a second electrode. The epitaxial layer includes a first semiconductor layer, a second semiconductor layer, and a light-emitting layer. A containing groove is formed in the first semiconductor layer, and a metal layer is arranged in the containing groove. The metal layer is in ohmic contact with the first semiconductor layer. The second semiconductor layer is provided with an inclined groove, and the transparent substrate is combined with the first semiconductor layer. The first electrode is arranged in the inclined groove, and the second electrode is arranged on the second semiconductor layer.

### CROSS REFERENCE TO RELATED APPLICATION

The present application is a non-provisional application and is a continuation application of PCT/CN2021/083586 filed on Mar. 29, 2021, PCT/CN2021/083586 claiming the benefit of priority to a Chinese Patent Application number CN202011337564.6, filed on Nov. 25, 2020, the disclosure of the above application is hereby incorporated by reference in its entirety for all purposes.

### TECHNICAL FIELD

The disclosure relates to the field of semiconductor devices, and in particular, relates to a light-emitting diode chip, its manufacturing method, and display devices that incorporate this light-emitting diode chip.

### BACKGROUND

Light Emitting Diode (LED) is a new generation of display technology. Compared with liquid crystal display in similar technology, it has higher photoelectric efficiency, higher brightness, higher contrast and lower power, and can realize flexible display in combination with a flexible panel. Such that it can be widely applied in the related fields. In the existing manufacturing process of the light emitting diode, the basic structure of the light emitting diode includes an N-type semiconductor layer, a P-type semiconductor layer, and a light-emitting layer arranged between the N-type semiconductor layer and the P-type semiconductor layer. When setting electrodes, one of the electrodes needs to sequentially pass through one semiconductor layer, the light-emitting layer, and then to the other semiconductor layer, in order to prevent metal breakage of the electrode. And an inclined groove is needed to sequentially connect one semiconductor layer, light-emitting layer, and to the other semiconductor layer. However, this arrangement means of the inclined groove is very difficult so that it needs to spend more process time, which may cause more area loss of the light-emitting layer and low luminous efficiency.

Therefore, reducing the area loss of the light-emitting layer and the process difficulty may be an urgent problem to be solved.

### BRIEF DESCRIPTION OF THE DISCLOSURE

The disclosure provides a light-emitting diode chip and a manufacturing method thereof, and a display device, which can solve the problems of large area loss and high process difficulty of a light-emitting layer of the light-emitting diode chip in the correlative technique.

A light-emitting diode chip includes a transparent substrate, an epitaxial layer, a first electrode, and a second electrode. The epitaxial layer includes a first semiconductor layer, a second semiconductor layer, and a light-emitting layer. Wherein the light-emitting layer is disposed between the first semiconductor layer and the second semiconductor layer. A containing groove is formed in the first semiconductor layer, wherein the bottom of the containing groove is not in contact with the light-emitting layer. A metal layer is formed in the containing groove, wherein the metal layer is in ohmic contact with the first semiconductor layer. An inclined groove is formed in the position, corresponding to the containing groove, of the second semiconductor layer. Wherein the inclined groove sequentially passes through the second semiconductor layer, the light-emitting layer, and the first semiconductor layer, such that the surface of the metal layer is at least partially exposed. The transparent substrate is combined with the side, provided with the containing groove, of the first semiconductor layer. The first electrode is disposed in the inclined groove, and the second electrode is disposed on the second semiconductor layer.

According to the light-emitting diode chip, the containing groove is formed in the first semiconductor layer, and a metal layer is arranged in the containing groove. Such that the length of the first electrode can be greatly shortened, and the position of the inclined groove can be shallower. Thus, the process difficulty is greatly reduced, and the area loss of the light-emitting layer is reduced, such that the light-emitting efficiency of the light-emitting diode is improved.

Based on the same inventive concept, the disclosure further provides a display device, wherein the display device includes a plurality of light-emitting diode chips.

Due to the fact that the display device is composed of a plurality of light-emitting diode chips, the display device has higher luminous efficiency.

Based on the same inventive concept, the disclosure further provides a manufacturing method of the light-emitting diode chip, including:

provide an epitaxial layer which includes a first semiconductor layer, a second semiconductor layer, and a light-emitting layer. Wherein the light-emitting layer is disposed between the first semiconductor layer and the second semiconductor layer; provide a containing groove on the first semiconductor layer; wherein the bottom of the containing groove is not in contact with the light-emitting layer;

provide a metal layer in the containing groove. Wherein the metal layer is in ohmic contact with the first semiconductor layer;

combine the side, provided with the containing groove, of the first semiconductor layer with a transparent substrate;

provide an inclined groove in the position, corresponding to the containing groove, of the second semiconductor layer. Wherein the inclined groove sequentially passes through the second semiconductor layer, the light-emitting layer, and the first semiconductor layer, such that the surface of the metal layer is at least partially exposed; and

manufacture a first electrode through the inclined groove and a second electrode on the second semiconductor layer.

According to the manufacturing method of the light-emitting chip, the containing groove is formed in the first semiconductor layer, and a metal layer is arranged in the containing groove. Such that the length of the first electrode can be greatly shortened, and the position of the inclined groove can be shallower. Thus the technology difficulty of manufacturing the light-emitting diode is greatly reduced, and the area loss of the light-emitting layer is reduced, such that the light-emitting efficiency of the light-emitting diode is improved.

### BRIEF DESCRIPTION OF THE DRAWINGS

FIG. 1 is a schematic structural diagram of a light-emitting diode chip in the existing technology.

FIG. 2 is a flowchart of a chip manufacturing method in an embodiment of the disclosure.

FIG. 3 is a schematic structural diagram of the light-emitting diode chip with a containing groove in an embodiment of the disclosure.

FIG. 4 is a schematic structural diagram of the light-emitting diode chip with a metal layer in the containing groove in an embodiment of the disclosure.

FIG. 5 is a schematic structural diagram of the light-emitting diode chip with an epitaxial layer on a transparent substrate in an embodiment of the disclosure.

FIG. 6 is a schematic structural diagram of the light-emitting diode chip with an inclined groove in an embodiment of the disclosure.

FIG. 7 is a schematic structural diagram of the light-emitting diode chip with an insulating layer in an embodiment of the disclosure.

FIG. 8 is a schematic structural diagram of the light-emitting diode chip with electrodes in an embodiment of the disclosure.

FIG. 9 is a schematic structural diagram of another light-emitting diode chip in an embodiment of the disclosure.

FIG. 10 is a flowchart of a chip manufacturing method in an embodiment of the disclosure.

### BRIEF DESCRIPTION OF THE REFERENCE SIGNS OF THE DRAWINGS

10—epitaxial layer;
101—first semiconductor layer;
102—light-emitting layer;
103—second semiconductor layer;
104—substrate;
105—transparent substrate;
106—transparent bonding layer;
107—transparent current conducting layer;
108—insulating layer;
109—second electrode;
110—first electrode;
20—containing groove;
30—metal layer;
40—inclined groove;
1081—first through hole;
1082—second through-hole.

### DETAILED DESCRIPTION

To facilitate to understand of the disclosure, more comprehensive description of the disclosure will be applied according to the reference drawings. A preferred embodiment of the disclosure is given in the drawings. However, the disclosure may be implemented in many different forms and not be limited to the embodiments described herein. On the contrary, the purpose of providing these embodiments is to provide a more thorough and comprehensive understanding of the disclosure.

Unless defined specially, all technical and scientific terminology used herein have the same meaning as commonly understood by ordinary skilled in the field of the disclosure. The terminology in the specification of the disclosure is only used for describing particular embodiments but not intended to limiting the disclosure.

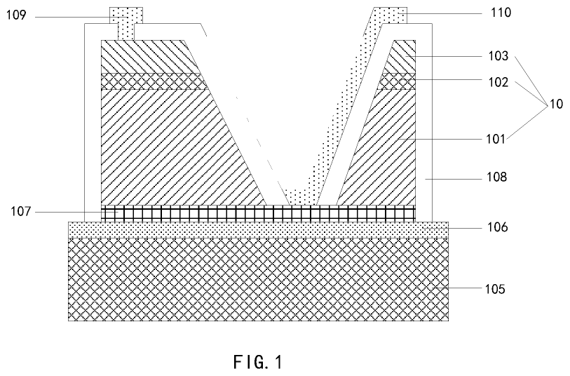

In some embodiments, referring to FIG. 1, the structure of a light-emitting diode generally includes a transparent substrate 105, an epitaxial layer 10, a transparent bonding layer 106 connected between the transparent substrate 105 and the epitaxial layer 10, a transparent current conducting layer 107 disposed at the bottom of the epitaxial layer 10, an insulating layer 108, and two electrodes. Wherein, the epitaxial layer 10 sequentially includes a first semiconductor layer 101, a light-emitting layer 102, and a second semiconductor layer 103 from the near to the distant of the transparent substrate 105. The two electrodes include the first electrode 110 and the second electrode 109, and the two electrodes need to be electrically connected to the two semiconductor layers, respectively.

Since the two semiconductor layers are stacked, the first electrode 110 needs to sequentially penetrate through the insulating layer 108, the second semiconductor layer 103, the light-emitting layer 102, and the first semiconductor layer 101 to reach the transparent current conducting layer 107 at the bottom of the first semiconductor layer 101. However, such a long electrode is easy to crack. An inclined groove is needed to improve the integral connection stability of the electrode, so that the inclined groove is very deep and penetrates through the entire epitaxial layer 10, and the area loss of the light-emitting layer 102 is serious. That will greatly affect the light-emitting efficiency.

The disclosure provides a solution that can solve the technical issue mentioned above. And the detailed contents thereof will be described in the following embodiments.

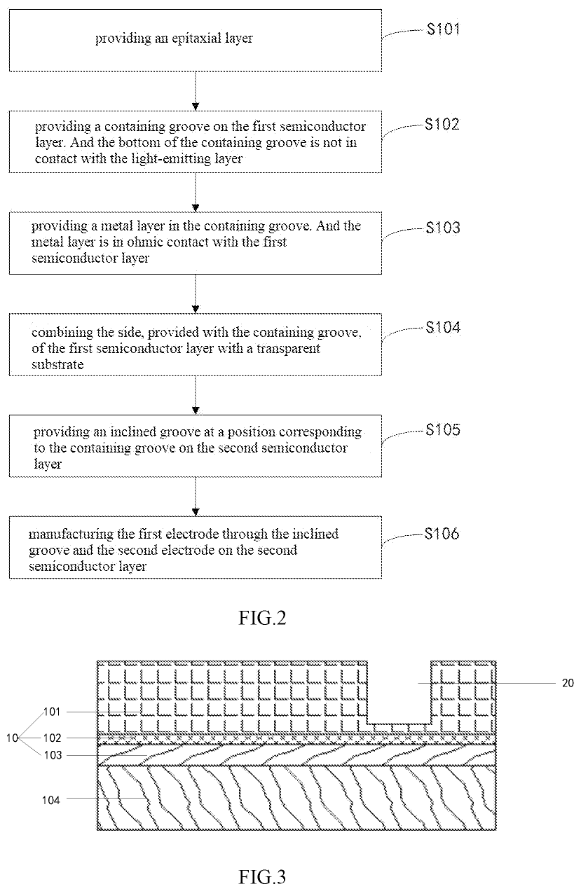

In some embodiments, as shown in FIG. 3 to FIG. 6, the light-emitting diode chip of the embodiment provides a containing groove 20 on the first semiconductor layer 101 and a metal layer 30 in the containing groove 20. That is equivalent to raise the conductive connection position on the first semiconductor layer 101. When forming the electrodes, the penetration depth of the inclined groove 40 is reduced. Without changing the angle of the inclined groove, the area loss of the light-emitting layer 102 caused by the inclined groove will be greatly reduced. And because the containing groove 20 is only arranged in the first semiconductor layer, the depth of the inclined groove 40 is reduced. Thus, the process difficulty of manufacturing the entire chip is reduced. For better illustration, taking the chip manufacturing method shown in FIG. 2 as an example to illustrate the disclosure.

Referring to FIG. 2 to FIG. 9, the chip manufacturing method includes, but is not limited to, the following operations:

S101, providing an epitaxial layer. The epitaxial layer 10 includes a first semiconductor layer 101, a second semiconductor layer 103, and a light-emitting layer 102. The light-emitting layer 102 is disposed between the first semiconductor layer 101 and the second semiconductor layer 103.

S102, providing a containing groove 20 on the first semiconductor layer 101. And the bottom of the containing groove 20 is not in contact with the light-emitting layer 102.

S103, providing a metal layer 30 in the containing groove. And the metal layer 30 is in ohmic contact with the first semiconductor layer 101.

S104, combining the side, provided with the containing groove 20, of the first semiconductor layer 101 with a transparent substrate 105.

S105, providing an inclined groove 40 at a position corresponding to the containing groove 20 on the second semiconductor layer 103. The inclined groove 40 sequentially passes through the second semiconductor layer 103, the light-emitting layer 102, and the first semiconductor layer 103, such that at least a part of the surface of the metal layer 30 is exposed.

S106, manufacturing the first electrode 110 through the inclined groove 40 and the second electrode 109 on the second semiconductor layer 103.

The chip manufacturing method in the embodiments of the disclosure is applied to manufacture light-emitting diode chips. The light-emitting diode chips include blue-light-diode chip, red-light-diode chip, green-light-diode chip, and the like. Distinguished by the luminous color, the light-emitting diode chip may be made of a compound such as gallium (Ga), arsenic (As), phosphorus (P), nitrogen (N), and the like. For example, a red light phosphated aluminum-gallium-indium-emitting diode chip (AlGaInP), a gallium nitride (GaN) light-emitting diode chip, and the like.

The light-emitting principle of the light-emitting diode is as follows: the light-emitting diode is the same as a common diode which is composed of a PN junction and has unidirectional conductivity. When the light emitting diode is applied with the forward voltage conforming to its unidirectional conduction direction, the holes from the P region to the N region and electrons injected into the P region from the N region are separately recombined with the electrons of the N region and the holes of the P region near the PN junction to generate the fluorescence of spontaneous radiation. The energy states of electrons and holes in different semiconductor materials are different. Therefore, the amount of released energy is different when the electrons and holes are recombined. The more energy released, the shorter the wavelength of the emitted light is. The diode that emits red light, green light, or yellow light is commonly used.

The light-emitting diode chip needs to dispose positive electrode and negative electrode separately on the P-type semiconductor layer and the N-type semiconductor layer. When the light-emitting diode chip is powered on, it emits light by the apart electrodes. For the light-emitting diode of the up-down stacked design, one of the two electrodes may be directly disposed on the surface of a semiconductor layer, and the other electrode must pass through the semiconductor layer, a light-emitting layer to the other semiconductor layer to connect the two semiconductor layers.

The epitaxial layer 10 includes two semiconductor layers and a light emitting layer 102 located between the two semiconductor layers. The two semiconductor layers include a first semiconductor layer 101 and a second semiconductor layer 103, the first semiconductor layer 101 and the second semiconductor layer 103 may be respectively one the p-type semiconductor and the other n-type semiconductor. Namely, if the first semiconductor layer 101 is a p-type semiconductor, then the second semiconductor layer 103 is an n-type semiconductor. And if the first semiconductor layer 101 is an n-type semiconductor, then the second semiconductor layer 103 is a p-type semiconductor. In this embodiment, although the semiconductor layers are distinguished as the first semiconductor layer 101 and the second semiconductor layer 103, the types of these semiconductor layers do not need to be limited herein.

To facilitate the arrangement of the electrodes, the containing groove 20 is provided/allocated on the first semiconductor layer 101. The containing groove 20 extends inward from the surface of the first semiconductor, and is not in contact with the light-emitting layer 102. Referring to FIG. 3, the containing groove 20 is a space structure with a bottom and a side wall. And the bottom of the containing groove 20 refers to a bottom surface opposite to the opening direction of the containing groove 20, and is not related to the placement direction of the epitaxial layer 10 and the first semiconductor layer 101.

The placement arrangement of the epitaxial layer 10, sequentially from top to down, includes the first semiconductor layer 101, light-emitting layer 102, and the second semiconductor layer 103. In this case, the opening direction of the containing groove 20 faces upward. Or the placement arrangement of the epitaxial layer 10, sequentially from top to down, include the second semiconductor layer 103, light-emitting layer 102, and the first semiconductor layer 101. And in this case, the opening direction of the containing groove 20 faces downward. In other words, the containing groove 20 in the embodiment of the disclosure only defines that the containing groove 20 is disposed inward from the outer surface of the first semiconductor layer 101, but does not define a specific spatial direction thereof. In addition, the embodiment of the disclosure does not define the opening shape of the containing groove 20, and the opening shape of the containing groove 20 may be a rectangle, a circular, an oval, a semicircular, a triangle, and the like.

Referring to FIG. 4, a metal layer 30 is disposed in the containing groove 20. And the metal layer 30 is in ohmic contact with the first semiconductor layer 101. The so-called “ohmic contact” refers to the formation of potential barrier layer when the semiconductor and metal contact, but when the doping concentration of the semiconductor is very high, electrons can tunnel through the potential barrier, thus forming low resistance ohmic contact. Ohmic contact is very important for semiconductor devices. It facilitates input and output currents by forming a good ohmic contact. And different formulations of alloys are often selected as ohmic contact materials for different semiconductor materials.

To form ohmic contact, the metal layer 30 may match work function with a gold-germanium alloy AuGe, a gold-tin alloy AuSn, a gold-zinc alloy AuZn, a gold-beryllium alloy AuBe, and the like. And the metal layer 30 may be an alloy material which can form an ohmic contact with the P-type semiconductor. The specific setting process of the metal layer 30 may be evaporation. The metal layer 30 is generally disposed at the bottom of the containing groove 20.

Based on different depths of the containing groove 20, the distance between the metal layer 30 and the light-emitting layer 102 as well as the second semiconductor layer 103 may be adjusted. The deeper the containing groove 20 is, the smaller the distance between the metal layer 30 and the light-emitting layer 102 as well as the second semiconductor layer 103. And the smaller the distance between the metal layer 30 and the light-emitting layer 102 as well as the second semiconductor layer 103 is, the smaller the depth required by the inclined groove 40 in the follow-up placement of the inclined groove 40. The arrangement of the containing groove 20 and metal layer 30 in this embodiment may not be necessary to provide a transparent current conducting layer on the surface of the first semiconductor layer 101. Thus, the technology difficulty and process will be reduced, and the cost will be saved. Wherein the surface of the metal layer 30 is at least partially exposed, because after the inclined groove 40 is provided, the inclined groove 40 penetrates to the metal layer 30 to expose the metal layer 30 through the inclined groove 40.

To emit light normally, the epitaxial layer 10 is fixedly connected to the transparent substrate 105. Namely, the first semiconductor layer 101 is combined with the transparent substrate 105. Specifically, a side, provided with the containing groove 20, of the first semiconductor layer 101 is in combination with the transparent substrate 105. The first semiconductor layer 101 is close to the transparent substrate 105, the second semiconductor layer 103 is away from the transparent substrate 105, and the light-emitting layers 102 is located between the first semiconductor layer 101 and the second semiconductor layer 103. The containing groove 20 is disposed on the first semiconductor layer 101. This is equivalent that the transparent substrate 105 encloses the position where the opening of the containing groove 20 is located.

Referring to FIG. 5, the transparent substrate 105 can connect with the epitaxial layer 10 by disposing a transparent bonding layer 106 between them. Namely, combining the side, provided with the containing groove 20, of the first semiconductor layer with a transparent layer 105 may include combining the side, provided with the containing groove 20, of the first semiconductor layer with the transparent layer 105 through a transparent bonding layer 106. The so-called transparent bonding layer 106 generally refers to transparent glue which can be transparent while achieving a fixed connection.

Referring to FIG. 3 and FIG. 4, in some embodiments, before providing the epitaxial layer 10, the manufacturing method may further include providing a substrate 104, and growing the epitaxial layer 10 on the substrate 104. The epitaxial layer 10 may be fabricated in advance on the substrate 104, and the substrate 104 is only a temporary carrier of epitaxial layer 10. The substrate 104 may be made of gallium arsenide (GaAs). Correspondingly, when the epitaxial layer 10 is grown on the substrate 104, fixedly connecting the side, provided with the containing groove 20, of the first semiconductor layer with a transparent layer 105 may include peeling the substrate 104 off the side, provided with the containing groove 20, of the first semiconductor layer is fixedly connected with a transparent layer 105. In other words, disposing the containing groove 20 on the first semiconductor layer 101 may be performed when the epitaxial layer 10 is disposed on the substrate 104. For the epitaxial layer 10 disposed on the substrate 104, the outermost semiconductor layer may be used as the first semiconductor layer 101 to arrange the containing groove 20.

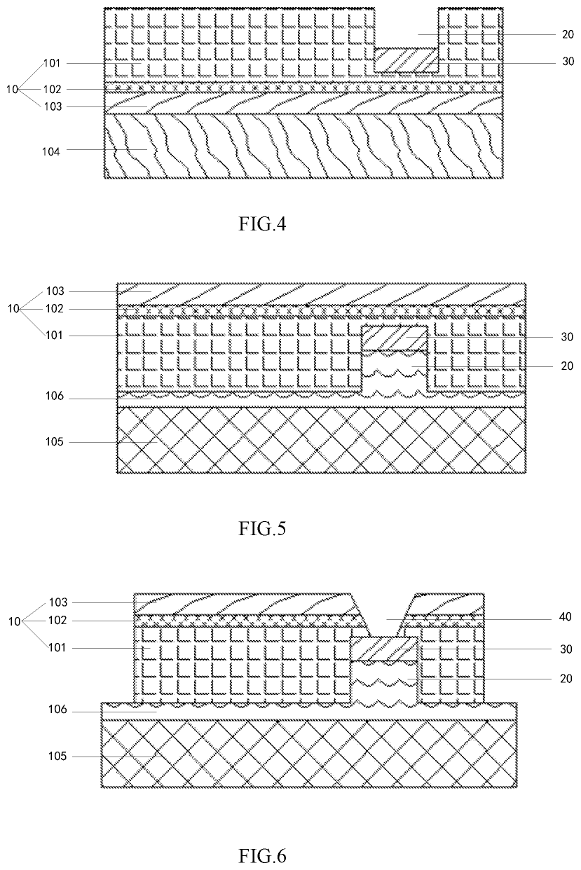

The light-emitting diode chip include two electrodes, namely a first electrodes 110 connected to the first semiconductor layer 101 and a second electrode 109 connected to the second semiconductor layer 103, respectively. The first electrode 110 and the second electrode 109 are insulated from each other. After the first electrode 110 and the second electrode 109 are applied with the positive voltage according to the unidirectional conduction direction of the light-emitting diode, light may be emitted. In the layered structure of the second semiconductor layer 103 and the first semiconductor layer 101, the second semiconductor layer 103 is far from the transparent substrate 105 and is located on the outer side, and the first semiconductor layer 101 is close to the transparent substrate 105 and is located on the inner side. Thus, the second electrode 109 is easier to be disposed by making ohmic contact between the second electrode 109 on the outermost side of the second semiconductor layer 103 and the second semiconductor layer 103. In addition, the first electrode 110 needs to pass through the second semiconductor layer 103, the light-emitting layer 102, and to the bottom of the containing groove 20 provided on the first semiconductor layer 101, till it is in communication with the metal layer 30 at the bottom of the containing groove 20. And the insulation between the first electrode 110 and the first electrode 110 should be maintained. The insulation between the first electrode 110 and the second electrode 109 is not only without direct contact, but also without directly connection through the first semiconductor layer 101. Due to the arrangement of the containing groove 20, the distance between the metal layer 30 and the light-emitting layer 102 as well as the second semiconductor layer 103 is small, the depth of the inclined groove 40 required by the second electrode 109 is shallower. Thus, the area loss of the light-emitting layer 102 is smaller. The inclined groove 40 in the embodiment of the disclosure indicates that the side surface of the inclined groove 40 is inclined and funnel-shaped to facilitate the arranging of the subsequent first electrode 110. Therefore, the breakage of the first electrode 110 may be reduced. If a straight groove is provided, the continuity requirement of the first electrode 110 is very high and easy to break. A specific shape of the inclined groove 40 in this embodiment may be a circular truncated cone shape, namely, a cavity of the rotating ladder body. The bevel angle of the inclined groove 40 may be between 30-90 degrees but less than 90 degrees, and the optimal angle is generally 60-70 degrees, please referring to FIG. 6.

To better achieve the insulation between the first electrode 110 and the second electrode 109, in some embodiments, after the inclined groove 40 is provided, the manufacturing method may further include the following steps.

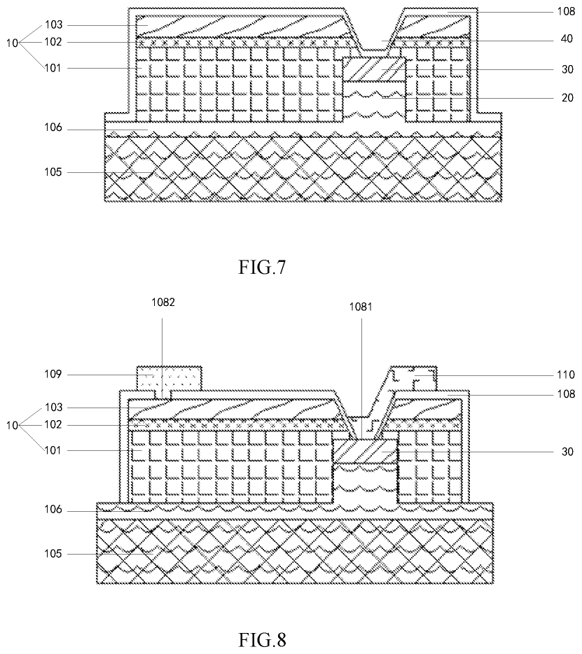

Referring to FIG. 7, covering the insulating layer 108 on the outer surface of the epitaxial layer 10. The outer surface of the epitaxial layer 10 refers to the surface exposed by the epitaxial layer 10 after being connected to the transparent substrate 105, and the surface of the epitaxial layer 10 connected to the transparent substrate 105 is excluded. The insulating layer 108 is disposed after the inclined groove 40, thus the insulating layer 108 may be disposed along the surface of the inclined groove 40 to cover the surface of the inclined groove 40. As a result, the second semiconductor layer 103, the light-emitting layer 102, and the first semiconductor layer 101 located on the side surface of the inclined groove 40 may be covered.

Once the insulating layer 108 is provided, the electrode is further disposed. Namely, manufacturing the first electrode 110 through the inclined groove 40 and manufacturing the second electrode 109 on the second semiconductor layer 102 further includes:

A first through hole 1081 is provided at a position corresponding to the inclined groove 40 on the insulating layer 108, and the first through hole 1081 is in communication with the metal layer 30. The first electrode 110 is provided on the inclined groove 40, and the first electrode 110 is connected to the metal layer 30 through the first through hole 1081;

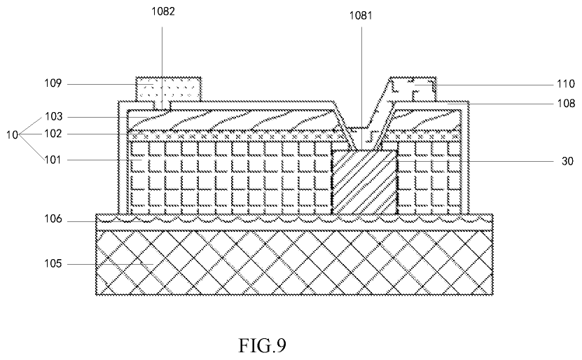

Referring to FIG. 8, a second through hole 1082 is formed in a position away from the inclined groove 40 on the insulating layer 108. The second through hole 1082 is in communication with the second semiconductor layer 103. The second electrode 109 is disposed on the second through hole 1082. And the second electrode 109 is in ohmic contact with the second semiconductor layer 103 through the second through hole 1082. The first electrode 110 is connected to the metal layer 30 through the first through hole 1081 provided on the insulating layer 108 corresponding to the inclined groove 40. And the second electrode 109 is in ohmic contact with the second semiconductor layer 103 through the second through hole 1082 provided on the insulating layer 108. For better insulation effect, the position between the first through hole 1081 and the second through hole 1082 should be far apart.

In some embodiments, the first semiconductor layer 101 may be a p-type semiconductor, and the second semiconductor layer 103 is correspondingly an n-type semiconductor. Correspondingly, the first electrode 110 is a positive electrode, and the second electrode 109 is a negative electrode.

In some embodiments, the containing groove 20 and the inclined groove 40 may be arranged in an etching manner. Namely, providing the containing groove 20 on the first semiconductor layer 101 may include:

Coating a photoresist layer the first semiconductor layer 101;

Patterning the photoresist layer;

Etching the first semiconductor layer 10 to form the containing groove 20 by using the patterned photoresist layer as a mask.

Providing the inclined groove 40 may include:

The inclined groove 40 is etched inwardly from the outer surface of the second semiconductor layer 103 by an etching process. And the bottom surface of the inclined groove 40 is in communication with the metal layer 30. The etching may be a dry etching or a wet etching.

Referring to FIG. 9, in some embodiments, the metal layer 30 may cover the entire space of the containing groove 20. The metal layer 30 may be mainly disposed on the bottom surface of the containing groove 20, or may fill the entire containing groove 20, as long as it may not be substantially affected by the light-emitting efficiency of the light-emitting chip.

It can be seen that according to the chip manufacturing method in the embodiments of the disclosure, the containing groove 20 is formed in the first semiconductor layer 101, and a metal layer 30 is arranged in the containing groove 20. Such that the length of the first electrode 110 can be greatly shortened, and the position of the inclined groove 40 can be shallower. Thus, the technology difficulty of manufacturing the light-emitting diode is greatly reduced, and the area loss of the light-emitting layer 102 is reduced, meaning that the light-emitting efficiency of the light-emitting diode is improved.

An embodiment of the disclosure further provides a light-emitting diode chip, which is prepared by the chip manufacturing method in the embodiments of the disclosure. Specifically, referring to FIG. 8 and FIG. 9, a light-emitting diode chip in the embodiment of the disclosure includes a transparent substrate, an epitaxial layer, a first electrode, and a second electrode. The epitaxial layer includes a first semiconductor layer, a second semiconductor layer, and a light-emitting layer. And the light-emitting layer is disposed between the first semiconductor layer and the second semiconductor layer.

A containing groove is formed in the first semiconductor layer, and the bottom of the containing groove is not in contact with the light-emitting layer. A metal layer is arranged in the containing groove, and the metal layer is in ohmic contact with the first semiconductor layer.

An inclined groove is formed in the position, corresponding to the containing groove, of the second semiconductor layer. And the inclined groove sequentially passes through the second semiconductor layer, the light-emitting layer, and the first semiconductor layer to expose at least part of the surface of the metal layer.

The transparent substrate is combined with one side, provided with the containing groove, of the first semiconductor layer.

The first electrode is disposed in the inclined groove, and the second electrode is disposed on the second semiconductor layer.

The light-emitting diode chip in the embodiment of the disclosure may include a blue-light diode chip, a red-light-diode chip, a green-light-diode chip, and the like. Distinguished by the luminous color, the light-emitting diode chip may be made of a compound such as gallium (Ga), arsenic (As), phosphorus (P), nitrogen (N), and the like. For example, a red light phosphated aluminum-gallium-indium-emitting diode chip (AlGaInP), a gallium nitride (GaN) light-emitting diode chip, and the like.

The light-emitting principle of the light-emitting diode is as follows: the light-emitting diode is the same as a common diode which is composed of a PN junction and has unidirectional conductivity. When the light emitting diode is applied with the forward voltage conforming to its unidirectional conduction direction, the holes from the P region to the N region and electrons injected into the P region from the N region, are separately recombined with the electrons of the N region and the holes of the P region near the PN junction to generate the fluorescence of spontaneous radiation. The energy states of electrons and holes in different semiconductor materials are different. Therefore, the amount of released energy is different when the electrons and holes are recombined. The more energy released, the shorter the wavelength of the emitted light is. The diode that emits red light, green light, or yellow light may be used.

In the structure of the light-emitting diode chip, the epitaxial layer 10 includes two semiconductor layers and a light emitting layer 102 located between the semiconductor layers, and the semiconductor layers include a first semiconductor layer 101 and a second semiconductor layer 103. The first semiconductor layer 101 and the second semiconductor layer 103 are respectively one p-type semiconductor and the other n-type semiconductor. Namely, if the first semiconductor layer 101 is a p-type semiconductor, then the second semiconductor layer 103 is an n-type semiconductor; or if the first semiconductor layer 101 is an n-type semiconductor, then the second semiconductor layer 103 is a p-type semiconductor. In this embodiment, although the semiconductor layers are distinguished as the first semiconductor layer 101 and the second semiconductor layer 103, the type of each semiconductor layer is not limited herein.

To facilitate to arrange the electrodes, the containing groove 20 is provided on the first semiconductor layer 101. The containing groove 20 extends inward from the surface of the first semiconductor, and is not in contact with the light-emitting layer 102. The embodiment of the disclosure does not define the opening shape of the containing groove 20, and the opening shape of the containing groove 20 may be a rectangle, a circular, an oval, a semicircular, a triangle, and the like.

A metal layer 30 is disposed in the containing groove 20, and the metal layer 30 is in ohmic contact with the first semiconductor layer 101. The metal layer 30 is generally disposed at the bottom of the containing groove 20. Based on different depths of the containing groove 20, the distance between the metal layer 30 and the light-emitting layer 102 as well as the second semiconductor layer 103 may be adjusted. The deeper the containing groove 20 is, the smaller the distance between the metal layer 30 and the light-emitting layer 102 as well as the second semiconductor layer 103. And the smaller the distance between the metal layer 30 and the light-emitting layer 102 as well as the second semiconductor layer 103 is, the smaller the depth required by the inclined groove 40 in the follow-up placement of the inclined groove 40. The surface of the metal layer 30 is at least partially exposed, because after the inclined groove 40 is provided, the inclined groove 40 penetrates to the metal layer 30 to expose the metal layer 30 through the inclined groove 40.

In some embodiments, the metal layer 30 may partially or totally fill the containing groove 20. The partially filling may indicate that the metal layer 30 occupies only a part of the space of the containing groove 20. and the totally filling may indicate that the metal layer 30 fills the entire the space of the containing groove 20.

The first semiconductor layer 101 is combined with the transparent substrate 105. Specifically, the layer, provided with containing groove 20, of the first semiconductor layer 101 is in combination with the transparent substrate 105. The first semiconductor layer 101 is close to the transparent substrate 105, and the second semiconductor layer 103 is away from the transparent substrate 105. Correspondingly, the light emitting layer 102 is located between the first semiconductor layer 101 and he second semiconductor layer 103. Since the containing groove 20 is provided on the first semiconductor layer 101, it is equivalent that the transparent substrate 105 encloses the position where the opening of the containing groove 20 is located.

In some embodiments, the light-emitting diode further includes a transparent bonding layer 106.

The transparent bonding layer 106 is configured to combine the side, provided with the containing groove, of the first semiconductor layer 101 with the transparent substrate 105. The so-called transparent bonding layer 106 generally refers to transparent glue that is transparent while achieving a fixed connection.

In some embodiments, the light-emitting diode further includes an insulating layer 108.

The insulating layer 108 is disposed on the second semiconductor layer 102. The first electrode 110 and the second electrode 109 are separately connected to the metal layer 30 and the second semiconductor layer 102 through the first through hole 1081 and the second through hole 1082 which penetrate through the insulating layer 108. The insulating layer 108 is configured to better achieve insulation between the first electrode 110 and the second electrode 109.

Once the insulating layer 108 is provided, the electrodes may then be disposed. Namely, the first electrode 110 is manufactured through the inclined groove 40, and the second electrode 109 is manufactured on the second semiconductor layer 102. Specifically, the first through hole 1081 is provided at a position corresponding to the inclined groove 40 on the insulating layer 108, and the first through hole 1081 is in communication with the metal layer 30. A first electrode 110 is provided on the inclined groove 40, and the first electrode 110 is connected to the metal layer 30 through the first through hole 1081.

A second through hole 1082 is provided on the insulating layer 108 away from the inclined groove 40, and the second through hole 1082 is in communication with the second semiconductor layer 103. A second electrode 109 is provided on the second through hole 1082, and the second electrode 109 is in ohmic contact with the second semiconductor layer 103 through the second through hole 1082. The first electrode 110 is connected with the metal layer 30 through the first through hole 1081 formed in the insulating layer 108 corresponding to the inclined groove 40. And the second electrode 109 is in ohmic contact with the second semiconductor layer 103 through the second through hole 1082 formed in the insulating layer 108. For better insulation effect, the distance between the first through hole 1081 and the second through hole 1082 may be far apart.

Since the light-emitting diode chip in the embodiments of the disclosure is manufactured by the above-mentioned chip manufacturing method, the containing groove 20 is provided on the first semiconductor layer 101, and the metal layer 30 is disposed in the containing groove 20. Thus, the length of the first electrode 110 is greatly shortened, and the arrangement position of the inclined groove 40 may be shallower, thereby greatly reducing the process difficulty and the area loss of the light-emitting layer 102. As a result, the light-emitting efficiency of the light-emitting diode chip may be improved.

An embodiment of the disclosure further provides a display device which includes a plurality of light-emitting diode chips.

Since the display device in the embodiments of the disclosure is composed of the same type of light-emitting diode chips which are manufactured by the chip manufacturing method in the embodiments of disclosure, the manufacturing process of the display device is simpler, and the light emitting efficiency is higher.

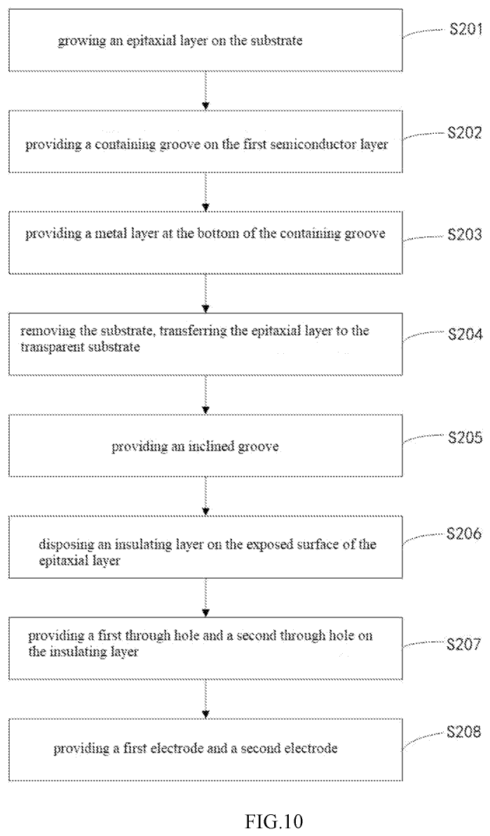

The chip manufacturing method in the embodiment of the disclosure will be illustrated as follows, illustrated by operations in FIG. 10.

S201, growing an epitaxial layer 10 on the substrate 104. The epitaxial layer 10 includes two semiconductor layers and a light-emitting layer 102. The semiconductor layers include a first semiconductor layer 101 and a second semiconductor layer 103. The first semiconductor layer 101 and the second semiconductor layer 103 are different, and the first semiconductor layer 101 and the second semiconductor layer 103 are respectively one a p-type semiconductor and the other a n-type semiconductor. The light-emitting layer is located between the p-type semiconductor and the n-type semiconductor. The second semiconductor layer 103 of the epitaxial layer 10 is connected to the substrate 104, and the first semiconductor layer 101 is away from the substrate 104.

S202, providing a containing groove 20 on the first semiconductor layer 101. And the bottom of the containing groove 20 is not in contact with the light-emitting layer 102, referring to FIG. 3.

S203, providing a metal layer 30 at the bottom of the containing groove 20.

And the metal layer 30 is in ohmic contact with the first semiconductor layer 101, referring to FIG. 4.

S204, removing the substrate 104, transferring the epitaxial layer 10 to the transparent substrate 105, and fixedly connecting to the transparent substrate 105 through a transparent bonding layer 106. As a result, the first semiconductor layer 101 in the epitaxial layer 10 is fixedly connected to the transparent substrate 105, as illustrated in FIG. 5.

S205, providing an inclined groove 40. The position of the inclined groove 40 is opposite to the position of the containing groove 20. The inclined groove 40 sequentially passes through the second semiconductor layer 103, the light-emitting layer 102, and the second semiconductor layer 103 from the outer surface of the second semiconductor layer 103, and is connected with the metal layer 30, as illustrated in FIG. 6.

S206, disposing an insulating layer 108 on the exposed surface of the epitaxial layer 10. The insulating layer 108 covers along the current surface of the epitaxial layer 10 and the inclined surface of the inclined groove 40, as illustrated in FIG. 7.

S207, providing a first through hole 1081 and a second through hole 1082 on the insulating layer 108. The first through hole 1081 is disposed at a position corresponding to the inclined groove 40, and is located at the bottom of the inclined groove 40 to communicate with the metal layer 30 in the first semiconductor layer 101. The second through hole 1082 is disposed away from the first through hole 1081, and communicates with the second semiconductor layer 103.

S208, providing a first electrode 110 and a second electrode 109. The first electrode 110 passes through the first through hole 1081 to connect to the metal layer 30 along the insulating layer 108 on the surface of the inclined groove 40 by means of evaporation. And the second electrode 109 also passes through the second through hole 1082, disposed on the insulating layer, to make in ohmic contact with the second semiconductor layer 103 by means of evaporation. Due to the arrangement of the insulating layer 108, the first electrode 110 and the second electrode 109 are insulated from each other, as illustrated in FIG. 8.

An embodiment of the disclosure further provides a chip manufacturing device which includes a processor, a memory, and a communication bus. The communication bus is configured to implement connection and communication between the processor and the memory. The processor is configured to execute one or more computer programs stored in the memory to implement the steps of the chip manufacturing method in the embodiments of disclosure.

An embodiment of the disclosure also provides a computer-readable storage medium which includes volatile or non-volatile, and removable or non-removable medium implemented in any method or technology for storing information, such as computer readable instructions, data structures, computer program modules, or other data. The computer readable storage medium includes, but is not limited to, a RAM (Random Access Memory), a ROM (Read-Only Memory), an EEPROM (Electrically Erasable Programmable Read Only Memory), a flash memory or other memory technology, a CD-ROM (DVD) or other optical disk storage, magnetic cassettes, magnetic tape, magnetic disk storage or other magnetic storage devices, or any other medium that can be used to store desired information which can be accessed by a computer.

The computer readable storage medium in the embodiments of the disclosure may be configured to store one or more computer programs, and one or more computer programs stored therein may be executed by a processor to implement at least one step performed by the chip manufacturing device.

An embodiment of the disclosure further provides a computer program (or computer software) which may be distributed on a computer readable medium and executed by a computing device to implement at least one step performed by the chip manufacturing device. And in some cases, at least one step shown or described may be performed in an order different from that described in the above embodiments.

An embodiment of the disclosure further provides a computer program product which included a computer-readable device. The computer-readable device stores a computer program as shown above. In this embodiment of the disclosure, the computer-readable device may include the computer-readable storage medium as shown above.

As can be seen, those skilled in the art should appreciate that all or some of the steps, systems, functional modules or units in the device disclosed above may be implemented as software (which may be implemented by computer program code executable by a computing device), firmware, hardware, and appropriate combinations thereof. In a hardware implementation, the division between the functional modules/units mentioned in the above description does not necessarily correspond to the division of the physical components. For example, one physical component may have multiple functions, or one function or step may be performed by a number of physical components in cooperation. Certain physical components or all of the physical components may be implemented as software executed by a processor, such as a central processor, a digital signal processor, or a microprocessor, or implemented as hardware, or implemented as an integrated circuit, such as an application specific integrated circuit.

Furthermore, it is well known to those skilled in the art that communication medium typically includes computer-readable instructions, data structures, computer program modules, or other data in a modulated data signal, such as a carrier or other transport mechanism, and may include any information delivery medium. Therefore, the disclosure is not limited to any specific combination of hardware and software.

It should be understood that the application of the disclosure is not limited to the examples mentioned above, and for those skilled in the art, improvements or transformations can be made according to the above description, and all these improvements and transformations shall fall within the protection scope of the appended claims of the disclosure.

What is claimed is:

1. A light-emitting diode chip, comprising:
a transparent substrate; an epitaxial layer; a first electrode; and a second electrode, the epitaxial layer comprising a first semiconductor layer, a second semiconductor layer, and a light-emitting layer, wherein
the light-emitting layer is disposed between the first semiconductor layer and the second semiconductor layer;
a containing groove is formed in the first semiconductor layer, wherein a bottom of the containing groove is close to the light-emitting layer and is not in contact with the light-emitting layer;
a metal layer is formed in the containing groove, wherein the metal layer is in ohmic contact with the first semiconductor layer;
an inclined groove is formed in a position, corresponding to the containing groove, of the second semiconductor layer, wherein the inclined groove sequentially passes through the second semiconductor layer, the light-emitting layer, and the first semiconductor layer, such that a surface of the metal layer is at least partially exposed;
the transparent substrate is combined with a side, provided with the containing groove, of the first semiconductor layer; and
the first electrode is disposed in the inclined groove, and the second electrode is disposed on the second semiconductor layer.

2. The light-emitting diode chip of the claim 1, wherein
the metal layer partially fills the containing groove.

3. The light-emitting diode chip of the claim 1, wherein
the metal layer fills up the containing groove.

4. The light-emitting diode chip of the claim 1, further comprising a transparent bonding layer, wherein
the transparent bonding layer is configured to combine a side, provided with the containing groove, of the first semiconductor layer with the transparent substrate.

5. The light-emitting diode chip of the claim 1, further comprising an insulating layer, wherein
the insulating layer is formed on the second semiconductor layer, and
the first electrode and the second electrode are separately connected to the metal layer and the second semiconductor layer through a first through hole and a second through hole penetrating through the insulating layer.

6. The light-emitting diode chip of the claim 1, wherein
the first semiconductor layer and the seconde semiconductor layer are of different type of semiconductor and are separately one of the p-type semiconductor and the n-type semiconductor.

7. The light-emitting diode chip of the claim 1, wherein
the containing groove is disposed to extend inward from the surface of the first semiconductor layer, and is not contact with the light-emitting layer.

8. The light-emitting diode chip of the claim 1, wherein
the bottom of the containing groove is the bottom surface which is opposite to an opening direction of the containing groove.

9. The light-emitting diode chip of the claim 8, wherein
the opening shape of the containing includes rectangle, circle, oval, semicircle, or triangle.

10. The light-emitting diode chip of the claim 1, wherein
the side of the inclined groove is an inclined surface, such that the inclined groove is funnel-shaped, and the angle of the inclined surface is between 30 degree to 90 degree but not includes the 90 degree.

11. A display device, comprising a plurality of light-emitting diode chips, wherein each of the light-emitting diode chips comprise:
a transparent substrate; an epitaxial layer; a first electrode; and a second electrode, the epitaxial layer comprising a first semiconductor layer, a second semiconductor layer, and a light-emitting layer, wherein
the light-emitting layer is disposed between the first semiconductor layer and the second semiconductor layer;
a containing groove is formed in the first semiconductor layer, wherein a bottom of the containing groove is not in contact with the light-emitting layer;
a metal layer is formed in the containing groove, wherein the metal layer is in ohmic contact with the first semiconductor layer;
an inclined groove is formed in a position, corresponding to the containing groove, of the second semiconductor layer, wherein the inclined groove sequentially passes through the second semiconductor layer, the light-emitting layer, and the first semiconductor layer, such that a surface of the metal layer is at least partially exposed;
the transparent substrate is combined with a side, provided with the containing groove, of the first semiconductor layer; and
the first electrode is disposed in the inclined groove, and the second electrode is disposed on the second semiconductor layer.

12. A manufacturing method of a light-emitting diode chip, the method comprising:
providing an epitaxial layer which comprises a first semiconductor layer, a second semiconductor layer, and a light-emitting layer, wherein the light-emitting layer is disposed between the first semiconductor layer and the second semiconductor layer;
providing a containing groove on the first semiconductor layer, wherein a bottom of the containing groove is not in contact with the light-emitting layer;
providing a metal layer in the containing groove, wherein the metal layer is in ohmic contact with the first semiconductor layer;
combining a side, provided with the containing groove, of the first semiconductor layer with a transparent substrate;
providing an inclined groove in a position, corresponding to the containing groove, of the second semiconductor layer, wherein the inclined groove sequentially passes through the second semiconductor layer, the light-emitting layer, and the first semiconductor layer, such that a surface of the metal layer is at least partially exposed; and
manufacturing a first electrode through the inclined groove and a second electrode on the second semiconductor layer.

13. The manufacturing method of the light-emitting diode chip of the claim 12, wherein before providing the epitaxial layer, the method further comprises:
providing a substrate and grow the epitaxial layer on the substrate.

14. The manufacturing method of the light-emitting diode chip of the claim 13, wherein the combining of the side, provided with the containing groove, of the first semiconductor layer with the transparent substrate comprises:
after fixedly connecting the side, provided with the containing groove, of the first semiconductor layer to the transparent substrate, striping the substrate.

15. The manufacturing method of the light-emitting diode chip of the claim 12, wherein the combining the side, provided with the containing groove, of the first semiconductor layer with the transparent substrate comprises:
combining the side, provided with the containing groove, of the first semiconductor layer with the transparent substrate through a transparent bonding layer.

16. The manufacturing method of the light-emitting diode chip of the claim 12, wherein after providing the inclined groove, the method further comprises:
covering an insulating layer on the outer surface of the epitaxial layer.

17. The manufacturing method of the light-emitting diode chip of the claim 16, wherein the manufacturing of the first electrode through the inclined groove and the second electrode on the second semiconductor layer comprises:
providing a first through hole in the position corresponding to the inclined groove on the insulating layer, wherein the first through hole is connected with the metal layer, a first electrode is arranged on the inclined groove, and the first electrode is connected with the metal layer through the first through hole; and
providing a second through hole in the position, away from the inclined groove, of the insulating layer, wherein the second through hole is connected with the second semiconductor layer; a second electrode is arranged on the second through hole, and the second electrode is in ohmic contact with the second semiconductor layer through the second through hole.

18. The manufacturing method of the light-emitting diode chip of the claim 12, wherein the providing of the containing groove on the first semiconductor layer comprises:
coating a photoresist layer on the first semiconductor layer;
patterning the photoresist layer; and
etching the first semiconductor layer to form the containing groove by using the patterned photoresist layer as a mask.

19. The manufacturing method of the light-emitting diode chip of the claim 12, wherein the providing of the inclined groove in the position, corresponding to the containing groove, of the second semiconductor layer comprises:
etching inwardly from the outer surface of the second semiconductor layer to form the inclined groove, wherein the bottom surface of the inclined groove is connected with the metal layer.

20. The manufacturing method of the light-emitting diode chip of the claim 12, wherein the metal layer is partially or fully filled with the containing groove.
